(19) United States
(12) Patent Application Publication
(10) Pub. No.: US 2024/0258486 A1
(43) Pub. Date: Aug. 1, 2024

(54) DISPLAY DEVICE AND METHOD FOR OPERATING THE SAME

(71) Applicant: LG Display Co., Ltd., Seoul (KR)

(72) Inventors: Dukkeun YOO, Seoul (KR); Kwangsu LIM, Seoul (KR); Yongmin HA, Seoul (KR)

(21) Appl. No.: 18/424,335

(22) Filed: Jan. 26, 2024

(30) Foreign Application Priority Data
Jan. 31, 2023 (KR) 10-2023-0013143

(51) Int. Cl. H01L 33/62; H01L 25/075; H01L 25/16; H01L 27/12; H01L 33/42

(52) U.S. Cl. CPC H01L 33/62; H01L 25/0753; H01L 25/167; H01L 27/124; H01L 33/42; H01L 2933/0016; H01L 2933/0066

(57) ABSTRACT

Disclosed is a display device including a wiring substrate including a first area having a plurality of link lines and a second area having a common line electrode. The display device includes a plurality of display parts on the wiring substrate and spaced apart from each other. The plurality of display parts includes a first area having a plurality of light-emitting elements and a plurality of signal lines and a second area having a partitioning-wall pattern. The display device includes a transmissive solution layer disposed between the wiring substrate and each of the display parts in the second area. The transmissive solution layer includes a plurality of electrophoretic particles. The second area of the display part includes a lower electrode under the partitioning-wall pattern.

### CROSS-REFERENCE TO RELATED APPLICATION

This application claims priority from Korean Patent Application No. 10-2023-0013143 filed on Jan. 31, 2023, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device, and more specifically, a display device which operates in a light-transmissive mode, or a light-blocking mode based on a use environment, and a method for operating the same.

### Description of Related Art

A display device is applied to various electronic devices such as TVs, mobile phones, laptops, and tablets. To this end, research to develop thinning, lightening, and low power consumption of the display device is continuing.

Among display devices, a light-emitting display device has a light-emitting element or a light source built therein and displays information using light generated from the built-in light-emitting element or light source. A display device including a self-light-emitting element may be implemented to be thinner than a display device with the built-in light source, and may be implemented as a flexible display device that may be folded, bent, or rolled.

The display device having the self-light-emitting element may include, for example, an organic light-emitting display device (OLED) including a light-emitting layer made of an organic material, or a micro-LED display device (micro light-emitting diode display device) including a light-emitting layer made of an inorganic material. In this regard, the organic light-emitting display device does not require a separate light source. However, due to material characteristics of the organic material that is vulnerable to moisture and oxygen, a defective pixel easily occurs in the organic light-emitting display device due to an external environment. On the contrary, the micro-LED display device includes the light-emitting layer made of the inorganic material that is resistant to moisture and oxygen and thus is not affected by the external environment and thus has high reliability and has a long lifespan compared to the organic light-emitting display device.

### BRIEF SUMMARY

Various aspects of the present disclosure provide a transparent display device with a large area size by arranging a plurality of display parts on an upper surface of a wiring substrate.

Various aspects of the present disclosure provide a display device configured to controlling transparency of the display device locally or transparency of a required area of an entire screen thereof.

Various aspects of the present disclosure provide a display device which switches to a light-transmissive mode or a light-blocking mode depending on the user's usage environment, thereby providing user convenience.

Various aspects of the present disclosure provide a method for operating a display device so as to control transparency of the display device.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other technical benefits and aspects of the present disclosure, as embodied and broadly described herein, a display device comprises a wiring substrate including a first area and a second area, a plurality of link lines in the first area of the wiring substrate, a common line electrode in the second area of the wiring substrate, a plurality of display parts on the wiring substrate and spaced apart from each other, the plurality of display parts including a first area and a second area, the plurality of display parts including a plurality of light-emitting elements and a plurality of signal lines in the first area of the display part and a partitioning-wall pattern in the second area of the display part, and a transmissive solution layer disposed between the wiring substrate and each of the display parts and corresponding to the second area, the transmissive solution layer including a plurality of electrophoretic particles. The second area of the display parts includes a lower electrode under the partitioning-wall pattern.

In another aspect, a method for operating a display device is disclosed, the display device includes, a wiring substrate including a first area having a plurality of link lines and a second area having a common line electrode and divided into a plurality of blocks, a plurality of display parts on the wiring substrate and spaced apart from each other, the plurality of display parts including a first area having a plurality of light-emitting elements and a plurality of signal lines and a second area having a partitioning-wall pattern, and a transmissive solution layer disposed between the wiring substrate and each of the display parts and corresponds to the second area of the display parts, the transmissive solution layer including a plurality of electrophoretic particles. The second area of the display parts may include a lower electrode under the partitioning-wall pattern. The method comprises supplying a power to at least one of the common line electrode and the lower electrode among the common line electrodes of blocks such that the plurality of electrophoretic particles migrate toward the partitioning-wall pattern so as to switch the second area into a light-transmissive area.

According to an aspect of the present disclosure, process optimization may be achieved by bonding (or attaching) a plurality of display parts onto a wiring substrate by a bonding member and electrically connecting the wiring substrate and the display part to each other by the bonding member without using a separate.

Furthermore, using a wiring substrate, a selected area may be selectively switched to the light-transmissive area or the light-blocking area. Thus, applicable fields of the display device according to an aspect of the present disclosure may be expanded compared to a display device whose an operation mode is limited to only the light-transmissive mode.

Furthermore, an area selected by a user may be switched to the light-transmissive area or the light-blocking area. Alternatively, a display device may operate selectively in the light-transmissive mode or the light-blocking mode, based on the use environment. This may improve user convenience.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are exemplary and explanatory and are intended to provide further explanation of the disclosure inventive concepts as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate aspects of the disclosure and together with the description serve to explain principles of the disclosure.

FIG. 1 illustrates a plan view of a display device according to an aspect of the present disclosure.

FIG. 2 is a plan view of an area 2 in FIG. 1.

FIG. 3 is a cross-sectional view of an area 3 in FIG. 2.

FIG. 4 is a cross-sectional view of an area 4 in FIG. 3.

FIGS. 5A, 5B, and 5C illustrate a change in a light-blocking percentage based on dispersion of electrophoretic particles.

FIG. 6 and FIG. 7 illustrates a method for operating a display device according to an aspect of the present disclosure.

FIG. 8 to FIG. 10 illustrates a display device according to another aspect of the present disclosure.

Throughout the drawings and the detailed description, unless otherwise described, the same drawing reference numerals should be understood to refer to the same elements, features, and structures. In some drawings, the sizes, lengths, and thicknesses of layers, regions and elements, and depiction of thereof may be exaggerated for clarity, illustration, and/or convenience.

### DETAILED DESCRIPTION

Reference is now made in detail to aspects of the present disclosure, examples of which may be illustrated in the accompanying drawings. In the following description, when a detailed description of well-known functions, structures or configurations may unnecessarily obscure aspects of the present disclosure, the detailed description thereof may have been omitted for brevity. Further, repetitive descriptions can be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the aspects described with reference to the accompanying drawings.

The present disclosure may however, be embodied in different forms and should not be construed as limited to the aspects set forth herein. Rather, these aspects examples and are provided so that this disclosure may be thorough and complete, and to assist to those of skill in the art to understand the inventive concepts without limiting the protected scope of the present disclosure.

Shapes (e.g., sizes, lengths, widths, heights, thicknesses, locations, radii, diameters, and areas), angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “made up of,” “formed of,” or the like is used with respect to one or more elements, one or more other elements may be added unless a term such as “only” or the like is used. The terms used in the present disclosure are merely used in order to describe example aspects, and are not intended to limit the scope of the present disclosure. The terms of a singular form may include plural forms unless the context clearly indicates otherwise.

The word “exemplary” is used to mean serving as an example or illustration. Aspects are example aspects. “Aspects,” “examples,” “aspects,” and the like should not be construed as preferred or advantageous over other implementations. An aspect, an example, an example aspect, an aspect, or the like may refer to one or more aspects, one or more examples, one or more example aspects, one or more aspects, or the like, unless stated otherwise.

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship, where the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more parts may be located between two other parts unless a more limiting term, such as “immediate(ly),” “direct(ly),” or “close(ly),” is used. For example, when a structure is described as being positioned “on,” “on a top of,” “upon,” “on top of,” “over,” “under,” “above,” “below,” “beneath,” “near,” “close to,” “adjacent to,” “beside,” or “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship when the temporal order is described as “after,” “subsequent,” “next,” “before,” “preceding,” “prior to,” or the like a case which is not consecutive or not sequential may be included and thus one or more other events may occur therebetween, unless a more limiting term, such as “just,” “immediate(ly),” or “direct(ly)” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It is understood that, although the terms “first”, “second,” or the like may be used herein to describe various elements (e.g., layers, films, regions, components, sections, or the like), these elements should not be limited by these terms. These terms are used only to partition one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, or the like) is “connected,” “coupled,” “attached,” “adhered,” or the like to another element, the element can not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, or the like) is “provided in,” “disposed in,” or the like in another element may be understood as that at least a portion of the element is provided in, disposed in, or the like in another element, or that the entirety of the element is provided in, disposed in, or the like in another element. The phase that an element (e.g., layer, film, region, component, section, or the like) “contacts,” “overlaps,” or the like with another element may be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other, and may be meant as lines or directions having wider directivities within the range within which the components of the present disclosure can operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and may be meant as directions having wider directivities within the range within which the components of the present disclosure can operate functionally.

The term “at least one” should be understood as including any and all combinations of one or more of the associated listed items. For example, each of the phrases of “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements “and/or” a third element should be understood as one of the first, second and third elements or as any or all combinations of the first, second and third elements. By way of example, A, B and/or C can refer to only A; only B; only C; any of A, B, and C (e.g., A, B, or C); or some combination of A, B, and C (e.g., A and B; A and C;

or B and C); or all of A, B, and C. Furthermore, an expression “A/B” may be understood as A and/or B. For example, an expression “A/B” can refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various aspects of the present disclosure may be partially or entirety coupled to or combined with each other, may be technically associated with each other, and may be variously inter-operated, linked or driven together. The aspects of the present disclosure may be implemented or carried out independently of each other, or may be implemented or carried out together in a co-dependent or related relationship. In one or more aspects, the components of each apparatus according to various aspects of the present disclosure are operatively coupled and configured.

Unless otherwise defined, all terms including technical and scientific terms used herein have the same meaning as commonly understood by one of ordinary skill in the art to example aspects belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating aspects.

Further, in a specific case, a term may be arbitrarily selected by the applicant, and in this case, the detailed meaning thereof will be described in a corresponding description herein. Therefore, the terms used herein should be understood based on not only the name of the terms, but also the meaning of the terms and the content hereof.

Hereinafter, a display device according to each aspect of the present disclosure will be described with reference to the attached drawings.

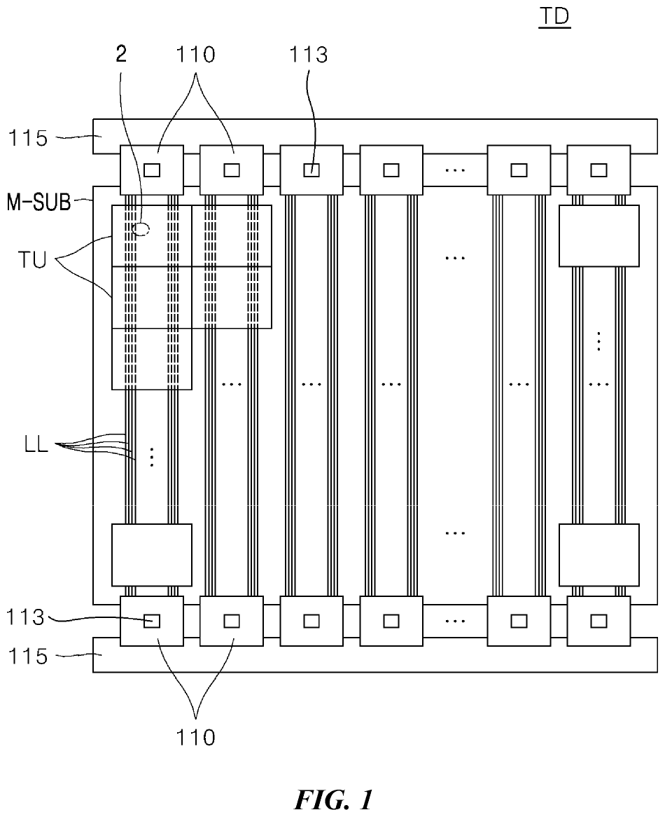

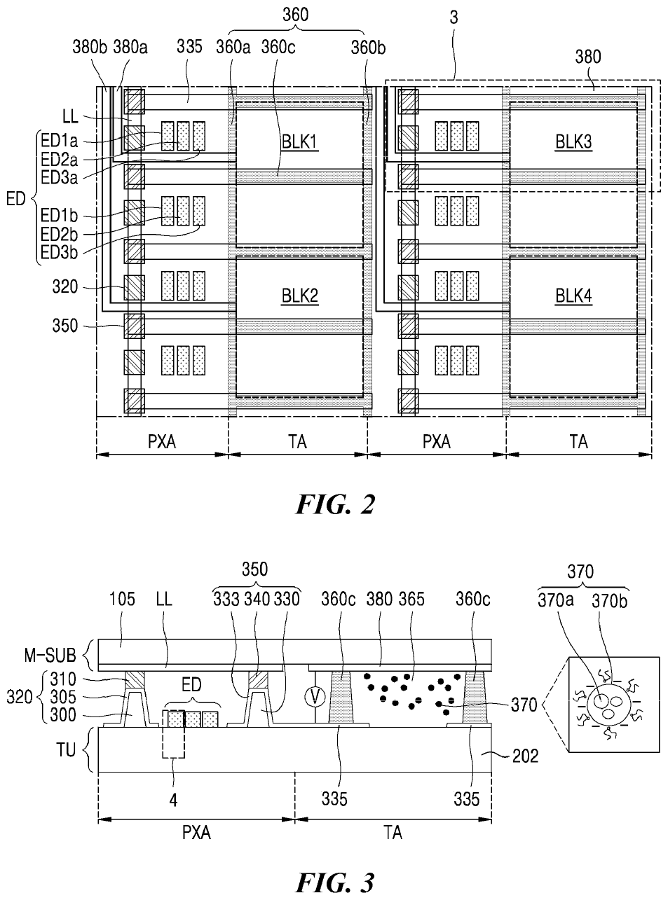

FIG. 1 illustrates a plan view of a display device according to an aspect of the present disclosure. FIG. 2 is a plan view of an area 2 in FIG. 1. FIG. 3 is a cross-sectional view of an area 3 in FIG. 2.

In FIG. 1, for convenience of illustration, a wiring substrate M-SUB, a plurality of link lines LL, a plurality of circuit films 110 on which a plurality of integrated circuit chips 113 are disposed, a printed circuit board 115, and a plurality of display parts TU among components of a display device TD are shown. Furthermore, FIG. 3 shows one first bonding member 320 and one second bonding member 350.

Referring to FIG. 1 to FIG. 3, the tiling display device TD according to an aspect of the present disclosure may include the wiring substrate M-SUB and a plurality of display parts TU disposed on the wiring substrate M-SUB. The display parts TU may be arranged along a first direction and a second direction that intersects the first direction. The first direction may be a row direction. The second direction may be a column direction. A first substrate 105 of the wiring substrate M-SUB and a second substrate 202 of the display part TU may include glass or transparent plastic. The wiring substrate M-SUB is composed of a single substrate, and the plurality of display parts TU are arranged so as to be spaced apart from each other in row and column directions. The plurality of display parts TU may be disposed on an upper surface of the wiring substrate M-SUB, and thus a transparent display device with a large size may be provided. The plurality of display parts TU may be arranged in a tiling manner and may be disposed on and bonded (or attached) to an upper surface of the wiring substrate M-SUB, such that a transparent display device with a large area size may be provided.

Each of the wiring substrate M-SUB and the display part TU may include a first area and a second area. The first area may include a plurality of pixel parts PXA, and the second area may include a switchable light-transmissive area TA. The pixel part PXA as the first area of the wiring substrate M-SUB may be disposed in a correspondence to (so as to overlap) the pixel part PXA as the first area of the display part TU. The switchable light-transmissive area TA as the second area of the wiring substrate M-SUB may be disposed in correspondence to (so as to overlap) the switchable light-transmissive area TA as the second area of the display part TU. Hereinafter, for convenience of description, the pixel part PXA as the first area of the wiring substrate M-SUB and the pixel part PXA as the first area of the display part TU will be collectively referred to as the pixel part PXA. The switchable light-transmissive area TA as the second area of the wiring substrate M-SUB and the switchable light-transmissive area TA as the second area of the display part TU will be collectively referred to as the switchable light-transmissive area TA.

The pixel part PXA may be an area where the light-emitting element ED disposed in the display part TU and various circuit elements configured to drive the light-emitting element ED are disposed. The switchable light-transmissive area TA may be a variable area that is converted into a light-transmissive area or a light-blocking area based on a voltage applied to the switchable light-transmissive area TA. The pixel parts PXA and the switchable light-transmissive areas TA may be arranged alternately with each other.

A plurality of link lines LL and voltage connection lines 380a and 380b may be disposed on the pixel part PXA of the wiring substrate M-SUB. A common line electrode 380 may be disposed on the switchable light-transmissive area TA of the wiring substrate M-SUB. The common line electrode 380 may be formed in blocks BLK1, BLK2, BLK3, and BLK4. The common line electrode 380 may include a transparent metal oxide such as indium-tin-oxide (ITO) or indium-zinc-oxide (IZO).

The common line electrode 380 disposed in each of the blocks BLK1, BLK2, BLK3, and BLK4 may transmit, to each of the blocks BLK1, BLK2, BLK3, and BLK4, a common line voltage of different values based on whether the switchable light-transmissive area TA is switched to the light-transmissive area or the light-blocking area. Thus, voltage connection lines 380a and 380b may extend from the pixel part PXA to each of the blocks BLK1, BLK2, BLK3, and BLK4 so as to be connected to the common line electrode 380. For example, the first voltage connection line 380a may be connected to the common line electrode 380 in the first block BLK1 so as to transfer the common line voltage to the first block BLK1, while the second voltage connection line 380b may be connected to the common line electrode 380 in the second block BLK2 so as to transfer the common line voltage to the second block BLK2.

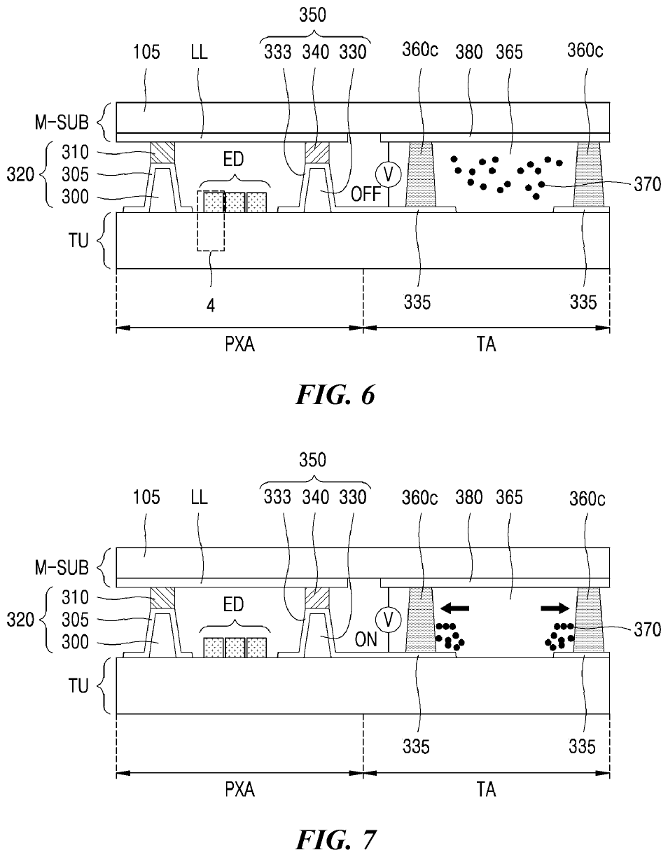

The first voltage connection line 380a and the second voltage connection line 380b may transmit, to a corresponding block, a common line voltage of different values based on whether the switchable light-transmissive area TA of the corresponding block is switched to the light-transmissive area or the light-blocking area. For example, when the switchable light-transmissive area TA of the first block BLK1 is converted to a light-transmissive area, and the switchable light-transmissive area TA of the second block BLK2 is configured to be a light-blocking area, the common line voltage may be transmitted to the common line electrode 380 in the first block BLK1 by the first voltage connection line 380a, while the common line voltage may not be transmitted to the second voltage connection line 380b. This will be described later with reference to FIG. 6 and FIG. 7.

The plurality of link lines LL may be disposed on the pixel part PXA of the wiring substrate M-SUB. The plurality of link lines LL may extend along one direction of the pixel part PXA. Referring to FIG. 1, a driver including the circuit film 110 and the printed circuit board 115 connected thereto may be disposed on an end of at least one side of the wiring substrate M-SUB. The integrated circuit chip 113 for transmitting various signals to the sub-pixels disposed in each display part or the wiring substrate M-SUB is mounted on the circuit film 110. The circuit film 110 may be connected to an end of the link line LL. For example, the signals transmitted to the sub-pixels may include high-potential voltage (Vdd), low-potential voltage (Vss), a scan signal, or a data signal. Furthermore, the signal transmitted to the wiring substrate M-SUB may include the common line voltage transmitted to the common line electrode 380 disposed at the switchable light-transmissive area TA.

The present disclosure presents a configuration in which the driver including the circuit film 110 on which the integrated circuit chip 113 is mounted and the printed circuit board 115 connected to the circuit film 110 is disposed at each of both opposing ends of the wiring substrate M-SUB. However, aspects of the present disclosure are not limited thereto.

The plurality of display parts TU disposed on the wiring substrate M-SUB may be electrically connected to the wiring substrate M-SUB by connection between a plurality of signal lines disposed at the plurality of display parts TU and the plurality of link lines LL disposed at the wiring substrate M-SUB. In this regard, the plurality of link lines LL may be disposed at the pixel part PXA of the wiring substrate M-SUB so as to overlap the pixel part PXA of the plurality of display parts TU, such that the plurality of link lines LL may not be exposed to an outside. Thus, an area size of a circuit area where the plurality of link lines LL are disposed may be reduced, thereby increasing a display area of the display device.

The display part TU may include the plurality of pixel parts PXA and the plurality of switchable light-transmissive areas TA. A light-emitting element ED and various circuit elements including a thin-film transistor configured to drive the light-emitting element ED may be disposed at each pixel part PXA of the display part TU.

The light-emitting element ED disposed at the pixel part PXA of the display part TU may include at least one light-emitting element disposed at each of a plurality of sub-pixels. For example, the light-emitting element ED may include a first light-emitting element ED1a, a second light-emitting element ED2a or a third light-emitting element ED3a that emits red (R), green (G), or blue (B) light, respectively. However, aspects of the present disclosure are not limited thereto. For example, each sub-pixel may further include a white light-emitting element that emits white light.

Furthermore, each of the plurality of sub-pixels may further include each of a plurality of redundant light-emitting elements for a repair process. For example, the redundant light-emitting element may include a first redundant light-emitting element ED1b, a second redundant light-emitting element ED2b, or a third redundant light-emitting element ED3b which corresponds to the first light-emitting element ED1a, the second light-emitting element ED2a, or the third light-emitting element ED3a, respectively.

The first bonding member 320 and the second bonding member 350 may be disposed on the pixel part PXA of the display part TU. The first bonding member 320 and the second bonding member 350 may be disposed to overlap the link line LL disposed at the wiring substrate M-SUB. The first bonding member 320 and the second bonding member 350 may be disposed in a same layer and may include a same material. The first bonding members 320 and the second bonding members 350 may be arranged alternately with each other.

The first bonding member 320 may be disposed to overlap the plurality of link lines

LL on the wiring substrate M-SUB so that the wiring substrate M-SUB and each display part TU may be electrically connected to each other by the first bonding member 320. For example, the first bonding member 320 may serve to transmit various signals transmitted via the link line LL to the thin-film transistor TFT or the light-emitting element ED. Process optimization may be achieved by bonding (or attaching) the plurality of display parts onto the wiring substrate M-SUB by the bonding member and electrically connecting the wiring substrate M-SUB and the display part to each other by the bonding member without using a separate side line.

The first bonding member 320 may include a first spacer pattern 300, a first conductive connection pattern 305, and a first adhesive pattern 310.

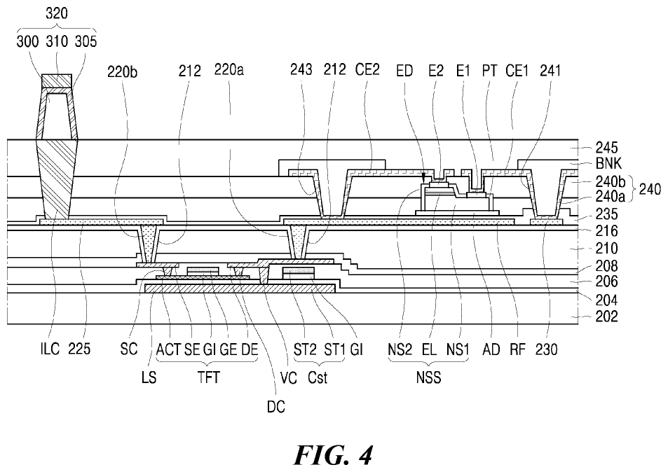

Hereinafter, referring to FIG. 4, the light-emitting element, and the thin-film transistor disposed in the display part TU and the first bonding member disposed on the display part TU will be described. FIG. 4 is a cross-sectional view of an area 4 in FIG. 3. FIG. 4 shows the light-emitting element and the thin-film transistor disposed in one sub-pixel for convenience of illustration. The sub-pixels may include the same configuration.

Referring to FIG. 4, one sub-pixel according to an aspect of the present disclosure may include the thin-film transistor TFT, a storage capacitor Cst, and various lines disposed on the second substrate 202. The thin-film transistor TFT may drive the light-emitting element ED. The storage capacitor Cst may store therein voltage so that the light-emitting element ED is configured to be the same state for one frame.

A light-blocking layer LS may be disposed on the second substrate 202. The light-blocking layer LS may reduce leakage current by preventing light incident from a position under a lower portion of the second substrate 202 from being incident to an active layer of the plurality of thin-film transistors. For example, the light-blocking layer LS may be disposed under the active layer ACT of the thin-film transistor TFT that functions as a driving transistor to prevent the light from being incident on the active layer ACT.

A buffer layer 204 may be disposed on the light-blocking layer LS. The buffer layer 204 may prevent impurities or moisture penetrating through the second substrate 202 from invading the thin-film transistor TFT. The buffer layer 204 may include an insulating material such as silicon oxide (SiOx) or silicon nitride (SiNx), but aspects of the present disclosure are not limited thereto.

The thin-film transistor TFT is disposed on the buffer layer 204. The thin-film transistor TFT may include a semiconductor layer ACT, a gate electrode GE, a source electrode SE, and a drain electrode DE. A gate insulating layer GI may be disposed between the semiconductor layer ACT and the gate electrode GE.

The semiconductor layer ACT may include an active area that overlaps the gate electrode GE to form a channel, and a source area and a drain area respectively located on both opposing sides of the active area. A first interlayer insulating film 206 is disposed on the gate electrode GE. The first interlayer insulating film 206 may receive therein a source contact SC and a drain contact DC. The source contact SC and drain contact DC may respectively contact portions of surfaces of the source area and the drain area of the semiconductor layer ACT. The source contact SC and the drain contact DC may be respectively electrically connected to the source electrode SE and the drain electrode DE located on a top surface of the first interlayer insulating film 206 and electrically connected to the source and drain areas of the semiconductor layer ACT, respectively.

The storage capacitor Cst may include a first capacitor electrode ST1 and a second capacitor electrode ST2. The first capacitor electrode ST1 may be disposed between the second substrate 202 and the buffer layer 204. The first capacitor electrode ST1 may be integrated with the light-blocking layer LS. A combination of the buffer layer 204 and the gate insulating layer GI may act as a dielectric layer of the storage capacitor Cst on the first capacitor electrode ST1. The second capacitor electrode ST2 may be disposed on the gate insulating layer GI. The second capacitor electrode ST2 may be formed of the same material as that of the gate electrode GE.

A first passivation layer 208 is disposed on the source electrode SE and the drain electrode DE. The first passivation layer 208 serves to protect the thin-film transistor TFT and may include an insulating material. A first planarization layer 210 is disposed on the first passivation layer 208. The first planarization layer 210 serves to planarize a surface step caused by an underlying element such as the thin-film transistor TFT. The first planarization layer 210 may be configured to include a photoactive compound (PAC). However, aspects of the present disclosure are not limited thereto.

The first planarization layer 210 may receive therein each contact hole 212 exposing a portion of a surface of each of the source electrode SE and the drain electrode DE. A second interlayer insulating film 216 may be disposed on a side surface of each contact hole 212 and the first planarization layer 210. Via contacts 220a and 220b that respectively fill the contact holes 212 may be disposed. The via contacts 220a and 220b may include the first via contact 220a and the second via contact 220b.

A reflective electrode RF connected to the first via contact 220a and a connection electrode 225 connected to the second via contact 220b may be disposed on the second passivation layer 216. The reflective electrode RF reflects light emitted from the light-emitting element toward the second substrate 202 so as to be directed out of the display area. The reflective electrode RF may include a highly reflective metal material. For example, the metal material with high reflectivity may include aluminum (Al), copper (Cu), silver (Ag), molybdenum (Mo), gold (Au), magnesium (Mg), calcium (Ca), or barium (Ba). The reflective electrode RF may include a single-layer structure or a stack structure of aluminum (Al), copper (Cu), silver (Ag), molybdenum (Mo), gold (Au), magnesium (Mg), calcium (Ca), or barium (Ba), or an alloy material of at least two thereof, but aspects of the present disclosure are not limited thereto.

The drain electrode DE connected to the reflective electrode RF and the first via contact 220a may be electrically connected to the light-blocking layer LS via a through-electrode extending through the interlayer insulating film 206 and the buffer layer 204.

The reflective electrode RF, the connection electrode 225, and a signal line 230 may be coplanar with each other. The reflective electrode RF, the connection electrode 225, and a signal line 230 may be disposed on a same plane. The third passivation layer 235 may not cover a portion of an upper surface of each of the reflective electrode RF, the connection electrode 225, and the signal line 230 so as to be exposed. The third passivation layer 235 may expose a portion of an upper surface of each of the reflective electrode RF, the connection electrode 225, and the signal line 230. The signal line 230 may include a plurality of signal lines. For example, the plurality of signal line may include a plurality of scan lines, a plurality of high-potential voltage (Vdd) lines, a plurality of data lines, and a plurality of reference voltage lines. The plurality of signal lines may be disposed on the second substrate 202 so as to be coplanar with each other. The plurality of signal lines may be disposed on the second substrate 202 so as to be a same plane. Furthermore, the plurality of signal lines may be formed of the same material as that of each of the reflective electrode RF and the connection electrode 225.

An adhesive layer AD may be disposed on the third passivation layer 235. The adhesive layer AD may serve to adhere the light-emitting element ED to the third passivation layer 235. The adhesive layer AD may be formed of a heat-curable material or a light-curable material. However, aspects of the present disclosure are not limited thereto.

The light-emitting element ED may be disposed on the adhesive layer AD. The light-emitting element ED according to an aspect of the present disclosure may be embodied as a micro-LED. The micro-LED may be an LED formed of an inorganic material and may refer to a light-emitting element of 100 or smaller. Furthermore, in an aspect of the present disclosure, an example in which the micro-LED is embodied as a horizontal micro-LED is described. However, aspects of the present disclosure are not limited thereto. For example, the light-emitting element may be embodied as a vertical micro-LED, a flip chip-shaped micro-LED, or a nanorod-shaped micro-LED.

The light-emitting element ED may include a nitride semiconductor structure NSS, a first electrode E1, and a second electrode E2. The nitride semiconductor structure NSS may include a first semiconductor layer NS1, an active layer EL disposed in one portion of the first semiconductor layer NS1, and a second semiconductor layer NS2 disposed on the active layer EL. The first electrode E1 may be disposed in the other side of the top surface of the first semiconductor layer NS1 where the active layer EL is not located, and the second electrode E2 is disposed on the second semiconductor layer NS2.

The first semiconductor layer NS1 may be a layer for supplying electrons to the active layer EL and may include a nitride semiconductor including first conductivity type impurity. For example, the first conductivity type impurity may include N type impurity. The active layer EL disposed in one portion of the first semiconductor layer NS1 may include a multi quantum well (MQW) structure. The second semiconductor layer NS2 may be a layer for injecting holes into the active layer EL. The second semiconductor layer NS2 may include a nitride semiconductor including second conductivity type impurity. For example, the second conductivity type impurity may include P type impurity.

A protective-layer pattern PT may cover an outer surface of the light-emitting element ED. The protective-layer pattern PT serves to supplement the characteristics of the element by preventing damage that may occur to a side portion of the nitride semiconductor structure NSS during a dry etching process to form the nitride semiconductor structure NSS.

The light-emitting element ED may be covered with an upper planarization layer 240. The upper planarization layer 240 may have a sufficient thickness to planarize an upper surface having steps caused due to underlying circuit elements. The upper planarization layer 240 may include a structure in which a second planarization layer 240a and a third planarization layer 240b are stacked. The upper planarization layer 240 may have opening holes 243 and 241 that expose portions of the surfaces of the reflective electrode RF and the signal line 230, respectively. The opening holes 241 and 243 may include the first opening hole 241 extending through the upper planarization layer 240 so as to expose the portion of the surface of the signal line 230 and the second opening hole 243 extending through the upper planarization layer 240 so as to expose the portion of the surface of the reflective electrode RF. Furthermore, the upper planarization layer 240 may not cover a portion of an upper surface of each of the first electrode E1 and the second electrode E2 of the light-emitting element ED so as to be exposed. The upper planarization layer 240 may expose a portion of an upper surface of the first electrode E1 and the second electrode E2 of the light-emitting element ED. The first electrode E1 and the second electrode E2 may be electrically connected to a first line electrode CE1 and a second line electrode CE2, respectively.

The first line electrode CE1 may extend to an exposed surface of the first opening hole 241. The second line electrode CE2 may extend to an exposed surface of the second opening hole 243. The first line electrode CE1 may be electrically connected to the signal line 230. The second line electrode CE2 may be electrically connected to the drain electrode DE via the reflective electrode RF.

The first line electrode CE1 and the second line electrode CE2 may be disposed at the same layer and formed of the same conductive material. In one example, the first line electrode CE1 and the second line electrode CE2 may include a transparent metal oxide such as indium-tin-oxide (ITO) or indium-zinc-oxide (IZO).

A bank BNK may be disposed on the upper planarization layer 240. The bank BNK may include an opaque material. However, aspects of the present disclosure are not limited thereto. The first opening hole 241 and the second opening hole 243 may be filled with a material constituting the bank BNK. Furthermore, the bank BNK may be disposed at a surrounding area (or a periphery area) around the light-emitting element ED excluding an area where the light-emitting element ED is disposed. A protective layer 245 may be disposed on the upper planarization layer 240 and the bank BNK. The protective layer 245 may prevent impurities from penetrating into the light-emitting element ED.

An interlayer connection electrode ILC extending through the protective layer 245 and the upper planarization layer 240 so as to contact a portion of a surface of the connection electrode 225 may be disposed. The interlayer connection electrode ILC may be electrically connected to the thin-film transistor TFT of the display part TU by the connection electrode 225.

The first bonding member 320 may be disposed on the protective layer 245. The first bonding member 320 may include a first spacer pattern 300, a first conductive connection pattern 305, and a first adhesive pattern 310. The first spacer pattern 300 may provide a gap and support between the wiring substrate M-SUB and the display part TU. The first spacer pattern 300 may have a taper shape in which a width of a lower surface thereof is wider than that of an upper surface thereof. However, aspects of the present disclosure are not limited thereto.

An outer surface of the first spacer pattern 300 may be covered with the first conductive connection pattern 305. For example, the first conductive connection pattern 305 may be disposed to cover an upper surface of the first spacer pattern 300 and surround a side surface thereof.

Furthermore, the first conductive connection pattern 305 may be electrically connected to the thin-film transistor TFT via the interlayer connection electrode ILC. In an aspect of the present disclosure, a configuration in which the bonding member 320 is electrically connected to the interlayer connection electrode ILC is described. However, aspects of the present disclosure are not limited thereto.

The first adhesive pattern 310 may be disposed on a portion of the first conductive connection pattern 305 covering the upper surface of the first spacer pattern 300. The first adhesive pattern 310 may bond (or attach) and fix the wiring substrate M-SUB and the display part TU to each other.

Furthermore, the first adhesive pattern 320 may have electrically conductive properties so as to transmit the driving signal transmitted via the link line LL of the wiring substrate M-SUB to the thin-film transistor TFT such that the light-emitting element of the display part TU emits light. Thus, the first adhesive pattern 310 may include a material having an electrically conductive properties and adhesive properties. For example, the first adhesive pattern 310 may include an anisotropic conductive film (ACF), but aspects of the present disclosure are not limited thereto.

The switchable light-transmissive area TA of the display part TU may be converted to the light-transmissive area or the light-blocking area based on a potential difference between the common line voltage applied to the common line electrode 380 disposed at the wiring substrate M-SUB and the high potential voltage Vdd transmitted via the link line LL disposed in the wiring substrate M-SUB.

The switchable light-transmissive area TA disposed in each display part TU may be an area in which an opaque material or a reflective material is not disposed. A partitioning-wall pattern 360 may be disposed on the switchable light-transmissive area TA of the display part TU. The partitioning-wall pattern 360 may have a shape surrounding the switchable light-transmissive area TA. The partitioning-wall pattern 360 may include carbon material. The partitioning-wall pattern 360 may include a first partitioning-wall pattern 360a, a second partitioning-wall pattern 360b, and a third partitioning-wall pattern 360c.

The first partitioning-wall pattern 360a and the second partitioning-wall pattern 360b may extend along one direction of the display part TU. For example, each of the first partitioning-wall pattern 360a and the second partitioning-wall pattern 360b may be disposed at a boundary area between the switchable light-transmissive area TA and the pixel part PXA. The first partitioning-wall pattern 360a and the second partitioning-wall pattern 360b may be arranged side by side and may be spaced apart from each other. The first partitioning-wall pattern 360a and the second partitioning-wall pattern 360b may extend along a column direction of the display part TU. The third partitioning-wall pattern 360c may be disposed between the first partitioning-wall pattern 360a and the second partitioning-wall pattern 360b. The third partitioning-wall pattern 360c may extend in a row direction intersecting the column direction in which the first and second partitioning-wall patterns 360a and 360b extend. Both outer portions of the third partitioning-wall pattern 360c may contact the first partitioning-wall pattern 360a and the second partitioning-wall pattern 360b, respectively.

A lower electrode 335 may be disposed on the switchable light-transmissive area TA of the display part TU. The lower electrode 335 may be disposed under the third partitioning-wall pattern 360c. For example, the lower electrode 335 may have a width larger than a width of a lower surface of the third partitioning-wall pattern 360c. Accordingly, the lower electrode 335 extends from the third partitioning-wall pattern 360c into the switchable light-transmissive area TA. A portion of the lower electrode 335 extending therefrom into the switchable light-transmissive area TA may be disposed to face the common line electrode 380 vertically. The lower electrode 335 may include a transparent metal oxide such as indium-tin-oxide (ITO) or indium-zinc-oxide (IZO) to have the transmittance of the switchable light-transmissive area TA.

The lower electrode 335 may extend from the third partitioning-wall pattern 360c toward the pixel part PXA of the display part TU so as be electrically connected to the second bonding member 350.

The second bonding member 350 may be disposed at the same layer as a layer in which the first bonding member 320 is disposed. The second bonding member 350 may be disposed so as to overlap and contact the link line LL so as to transmit the high-potential voltage (Vdd) transmitted by the link line LL to switchable light-transmissive area TA via the lower electrode 335. The second bonding member 350 may include a second spacer pattern 330, a second conductive connection pattern 333, and a second adhesive pattern 340. The second spacer pattern 330 may provide a gap and support between the wiring substrate M-SUB and the display part TU. The second spacer pattern 330 may have a taper shape. However, aspects of the present disclosure are not limited thereto.

An outer surface of the second spacer pattern 330 may be covered with the second conductive connection pattern 333. For example, the second conductive connection pattern 333 may be disposed to cover an upper surface of the second spacer pattern 330 and surround a side surface thereof. A portion of the second conductive connection pattern 333 may extend into the switchable light-transmissive area TA so as to act as the lower electrode 335 disposed under the third partitioning-wall pattern 360c. The second adhesive pattern 340 may be disposed on a portion of the second conductive connection pattern 333 covering the upper surface of the second spacer pattern 330. The second adhesive pattern 340 may bond and fix the wiring substrate M-SUB and the display part TU to each other.

Furthermore, the second adhesive pattern 340 may be electrically conductive so as to apply the high-potential voltage (Vdd) transmitted via the link line LL of the wiring substrate M-SUB to the lower electrode 335 in the switchable light-transmissive area TA. Thus, the second adhesive pattern 340 may include a material having electrically conductive properties and adhesive properties. For example, the second adhesive pattern 340 may include an anisotropic conductive film (ACF), but aspects of the present disclosure are not limited to.

In a portion of the switchable light-transmissive area TA surrounded with the partitioning-wall pattern 360, a transmissive solution layer 365 including a plurality of electrophoretic particles 370 may be disposed. The transmissive solution layer 365 including the plurality of electrophoretic particles 370 may be sealed with the common line electrode 380, the second substrate 202, and the partitioning-wall pattern 360 disposed between the wiring substrate M-SUB and the display part TU.

Referring to FIG. 3, each of the electrophoretic particles 370 may include a black pigment 370a and a polymer 370b surrounding the black pigment 370a. The plurality of electrophoretic particles 370 are dispersed in a transmissive solution layer 365 including a dispersant and a solvent. Each of the plurality of electrophoretic particles 370 may be charged with a negative-charge and may have a single polarity.

The switchable light-transmissive area TA may be switched to the light-transmissive area or the light-blocking area by controlling the dispersion of the plurality of electrophoretic particles 370 based on a potential difference between the common line voltage applied to the common line electrode 380 disposed at the wiring substrate M-SUB and the high voltage potential voltage (Vdd) transmitted by the link line LL disposed in the wiring substrate M-SUB.

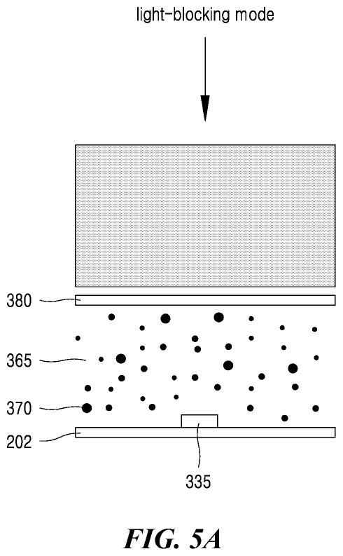

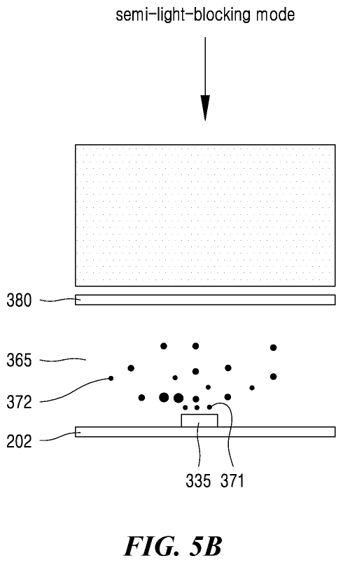

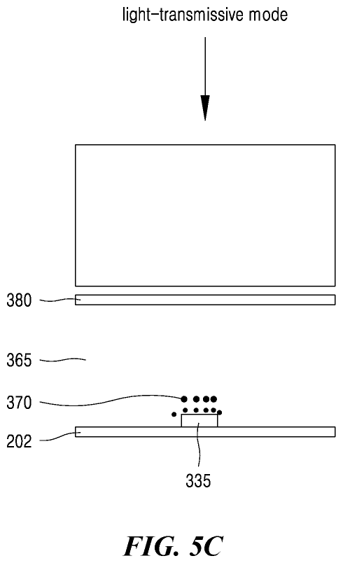

FIGS. 5A, 5B, and 5C illustrate a change in a light-blocking percentage based on the dispersion of electrophoretic particles. For convenience of illustration, FIGS. 5A, 5B, and 5C show the second substrate 202, the common line electrode 380, the lower electrode 335, the electrophoretic particles 370, and the transmissive solution layer 365 in the switchable light-transmissive area TA.

Referring to FIGS. 5A, 5B, and 5C, the transmissive solution layer 365 including the plurality of electrophoretic particles 370 may be disposed on an area of the second substrate 202 where the lower electrode 335 and the common line electrode 380 are spaced apart from each other vertically. The plurality of electrophoretic particles 370 may include black particles. The common line electrode 380 may be disposed on the second substrate 202 and extend across an entire surface of the second substrate 202 in the switchable light-transmissive area TA. Light may be emitted toward the common line electrode 380. The lower electrode 335 may be disposed on the second substrate 202 so as to have a predetermined pattern shape. For example, the lower electrode 335 may extend along the shape of the third partitioning-wall pattern 360c in FIG. 2.

In a first state (see FIG. 5A) in which power is not applied to the common line electrode 380, the plurality of electrophoretic particles 370 are widely dispersed within the transmissive solution layer 365, so that a light-blocking state is achieved in which the switchable light-transmissive area TA does not transmit light therethrough. When the potential difference between the voltage of the lower electrode 335 and the voltage of the common line electrode 380 is generated while the switchable light-transmissive area TA is in the light-shielding state, the dispersion of the electrophoretic particles 370 may be controlled such that the light-blocking percentage of the switchable light-transmissive area TA may be adjusted. For example, as shown in FIG. 5C, when the first common line voltage is applied to the common line electrode 380 such that the potential difference between the voltage of the lower electrode 335 and the voltage of the common line electrode 380 is generated, the electrophoretic particles 370 which have been widely dispersed within the transmissive solution layer 365 may be concentrated on the lower electrode 335. The first common line voltage may have sufficient intensity such that the electrophoretic particles 370 can be concentrated on the lower electrode 335. Accordingly, a light-transmissive state is achieved in which the switchable light-transmissive area TA is transmissive, such that an object or an image positioned in an opposite manner to the second substrate 202 is visible through the switchable light-transmissive area TA.

Furthermore, as shown in FIG. 5B, a second common line voltage which is different from the first common line voltage may be applied to the common line electrode 380. The second common line voltage may have a relatively smaller intensity than that of the first common line voltage which has the sufficient intensity to allow all electrophoretic particles 370 to migrate to the lower electrode 335.

When the second common line voltage is applied, some 371 of the electrophoretic particles 370 dispersed in the transmissive solution layer 365 may migrate to the lower electrode 335, while the remaining electrophoretic particles 372 may be dispersed within the transmissive solution layer 365. Accordingly, a semi-light-emitting state in which light partially transmits through the switchable light-transmissive area TA may be achieved.

Based on the characteristics of these electrophoretic particles of the switchable light-transmissive area TA, a required area may be converted to the light-transmissive area or the light-blocking area. This will be described with reference to the drawings.

FIG. 6 and FIG. 7 illustrates a method for operating a display device according to an aspect of the present disclosure.

Referring to FIG. 6, in a power-off (Voff) state in which power is not applied to the common line electrode 380, the plurality of electrophoretic particles 370 are widely dispersed within the transmissive solution layer 365. Accordingly, the switchable light-transmissive area TA may be a light-blocking state that does not transmit the light.

While the switchable light-transmissive area TA is in the light-blocking state, the common line voltage is applied to the common line electrode 380 in a power on (Von) state as shown in FIG. 7, such that the potential difference between the voltage of the lower electrode 335 and the voltage of the common line electrode 380 is generated. Thus, the electrophoretic particles 370 which have been widely dispersed within the transmissive solution layer 365 migrate to a position where the lower electrode 335 is disposed. For example, in an aspect of the present disclosure, the lower electrode 335 may be disposed under the third partitioning-wall pattern 360c of the partitioning-wall pattern 360. Thus, the electrophoretic particles 370 migrate toward the third partitioning-wall pattern 360c, as indicated by the arrow in FIG. 7. Thus, light transmits through the transmissive solution layer 365 filling the switchable light-transmissive area TA surrounded with the partitioning-wall pattern 360. Thus, the switchable light-transmissive area TA may be switched to a light-transmissive area in which an object or an image positioned in an opposite manner to the second substrate 202 is visible.

The switchable light-transmissive area TA may be converted to the transmissive area or the light-blocking area in each of the blocks BLK1, BLK2, BLK3, and BLK4, by transmitting different values of the common line voltage to different blocks BLK1, BLK2, BLK3, and BLK4 to generate different potential differences in different blocks BLK1, BLK2, BLK3, and BLK4, respectively. For example, the switchable light-transmissive area TA of the first block BLK1 may be converted to a light-transmissive area, and the switchable light-transmissive area TA of the second block BLK2 may be configured to be a light-blocking area. In this case, the display device may transmit the common line voltage to the common line electrode 380 in the first block BLK1 by the first voltage connection line 380a, while not transmitting the common line voltage to the second voltage connection line 380b. In this manner, the switchable light-transmissive area TA of each of the blocks BLK1, BLK2, BLK3, and BLK4 may be selectively converted to the transmissive area or the light-blocking area.

Accordingly, the area selected by the user may be switched to the light-transmissive area or the light-blocking area. Alternatively, the display device may operate selectively in the light-transmissive mode or the light-blocking mode, based on the use environment. This may improve user convenience. Furthermore, applicable fields of the display device according to an aspect of the present disclosure may be expanded compared to a display device whose an operation mode is limited to only the light-transmissive mode.

In one example, the lower electrode spaced apart from the common line electrode may be configured to be electrically connected to one of the electrodes of the thin-film transistor. In this case, the second bonding member 350 disposed on the pixel part PXA of the display part TU may be omitted. Accordingly, since only the first bonding member 320 is disposed on the pixel part PXA of the display part TU, the process margin may be improved. Furthermore, omitting the second bonding member 350 may allow the process to be simplified and may allow a process optimization to be realized. This will be described with reference to the drawings.

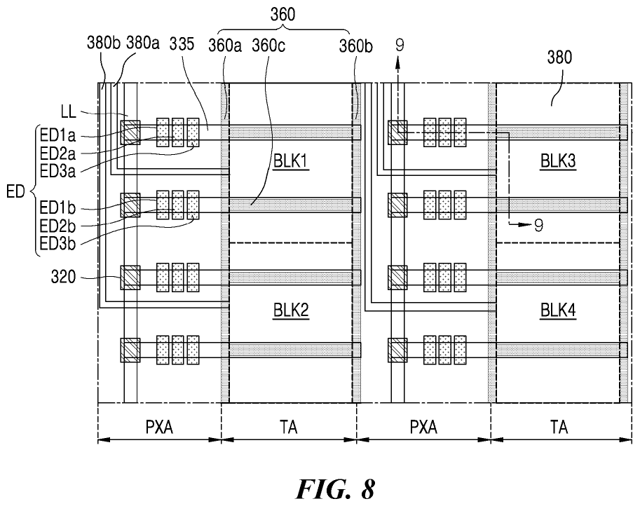

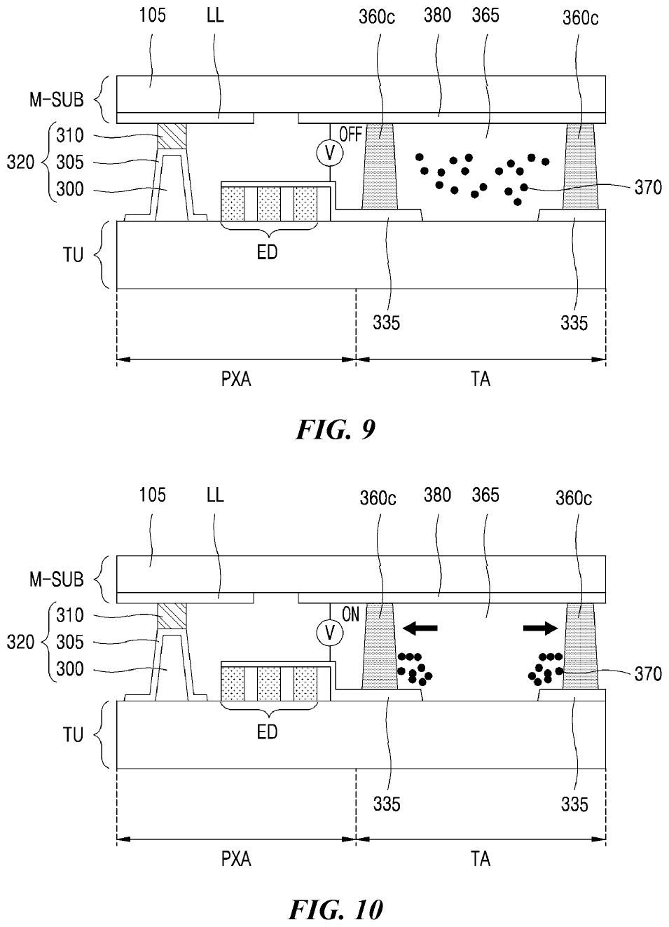

FIG. 8 to FIG. 10 illustrate a display device according to another aspect of the present disclosure. FIG. 9 is a cross-sectional view of an area 9 in FIG. 8. FIG. 9 and FIG. 10 illustrate an operation of the display device according to another aspect of the present disclosure. In this regard, the display device according to another aspect of the present disclosure has the same configuration as that of FIG. 2 and FIG. 3 except for absence of the second bonding member and a configuration of the lower electrode. Accordingly, the components indicated with the same reference numerals as in FIG. 2 may be briefly described or descriptions thereof may be omitted.

Referring to FIG. 8 and FIG. 9, the display device according to another aspect of the present disclosure may include the plurality of pixel part PXA and the plurality of switchable light-transmissive areas TA. The pixel part PXA of the wiring substrate M-SUB may correspond to (overlap) the pixel part PXA of the display part TU, and the switchable light-transmissive area TA of the wiring substrate M-SUB may correspond to (overlap) the switchable light-transmissive area TA of the display part TU.

The plurality of link lines LL and the voltage connection lines 380a and 380b may be disposed in the pixel part PXA of the wiring substrate M-SUB. The common line electrode 380 may be disposed in the switchable light-transmissive area TA of the wiring substrate M-SUB. The common line electrode 380 may be disposed on blocks BLK1, BLK2, BLK3, and BLK4.

The common line electrode 380 disposed in each of the blocks BLK1, BLK2, BLK3, and BLK4 may transmit, to each of the blocks BLK1, BLK2, BLK3, and BLK4, a common line voltage of different values depending on whether the switchable light-transmissive area TA is switched to the light-transmissive area or the light-blocking area. To this end, the voltage connection lines 380a and 380b may extend from the pixel part PXA to each of the blocks BLK1, BLK2, BLK3, and BLK4 so as to be connected to the common line electrode 380. For example, the first voltage connection line 380a may be connected to the common line electrode 380 in the first block BLK1 so as to transfer the common line voltage to the first block BLK1, while the second voltage connection line 380b may be connected to the common line electrode 380 in the second block BLK2 so as to transfer the common line voltage to the second block BLK2.

Each of the first voltage connection line 380a and the second voltage connection line 380b may transmit, to a corresponding block, a common line voltage of different values depending on whether the switchable light-transmissive area TA of the corresponding block is switched to the light-transmissive area or the light-blocking area. For example, when the switchable light-transmissive area TA of the first block BLK1 is converted to a light-transmissive area, and the switchable light-transmissive area TA of the second block BLK2 is configured to be a light-blocking area, the common line voltage may be transmitted to the common line electrode 380 in the first block BLK1 via the first voltage connection line 380a, while the common line voltage may not be transmitted to the second voltage connection line 380b.

The wiring substrate M-SUB may include the plurality of link lines LL extending in one direction of the pixel part PXA. The plurality of display parts TU disposed on the wiring substrate M-SUB may be electrically connected to the wiring substrate M-SUB via connections between a plurality of signal lines disposed in the plurality of display parts TU and the plurality of link lines LL disposed in the wiring substrate M-SUB.

The display part TU may include the plurality of pixel parts PXA and the plurality of switchable light-transmissive areas TA. The light-emitting element ED and various circuit elements including a thin-film transistor configured to drive the light-emitting element ED may be disposed at each pixel part PXA of the display part TU.

The light-emitting element ED disposed in the pixel part PXA of the display part TU may include at least one light-emitting element disposed at each of a plurality of sub-pixels. For example, the light-emitting element ED may include a first light-emitting element ED1a, a second light-emitting element ED2a or a third light-emitting element ED3a that emits red (R), green (G), or blue (B) light, respectively. However, aspects of the present disclosure are not limited thereto. For example, each sub-pixel may further include a white light-emitting element that emits white light.

Furthermore, each of the plurality of sub-pixels may further include each of a plurality of redundant light-emitting elements for a repair process. For example, the redundant light-emitting element may include a first redundant light-emitting element ED1b, a second redundant light-emitting element ED2b, or a third redundant light-emitting element ED3b which corresponds to the first light-emitting element ED1a, the second light-emitting element ED2a, or the third light-emitting element ED3a, respectively.

The first bonding member 320 that overlaps the link line LL disposed at the wiring substrate M-SUB may be disposed on the pixel part PXA of the display part TU. The first bonding member 320 may be disposed to overlap the plurality of link lines LL on the wiring substrate M-SUB so that the wiring substrate M-SUB and each display part TU may be electrically connected to each other by the first bonding member 320. For example, the first bonding member 320 may serve to transmit various signals transmitted by the link line LL to the thin-film transistor TFT or the light-emitting element ED. Process optimization may be achieved by bonding (or attaching) the plurality of display parts onto the wiring substrate M-SUB by the bonding member and electrically connecting the wiring substrate M-SUB and the display part to each other using the bonding member without using a separate side line. The first bonding member 320 may include the first spacer pattern 300, the first conductive connection pattern 305, and the first adhesive pattern 310.

The switchable light-transmissive area TA of the display part TU may be converted to the light-transmissive area or the light-blocking area based on a potential difference between the common line voltage applied to the common line electrode 380 disposed in the wiring substrate M-SUB and the high potential voltage (Vdd) transmitted via the link line LL disposed at the wiring substrate M-SUB.

The partitioning-wall pattern 360 may be disposed on the switchable light-transmissive area TA of the display part TU. The partitioning-wall pattern 360 may include the first partitioning-wall pattern 360a, the second partitioning-wall pattern 360b, and the third partitioning-wall pattern 360c. The first partitioning-wall pattern 360a and the second partitioning-wall pattern 360b may extend along one direction of the display part TU. For example, each of the first partitioning-wall pattern 360a and the second partitioning-wall pattern 360b may be disposed at a boundary area between the switchable light-transmissive area TA and the pixel part PXA. The first partitioning-wall pattern 360a and the second partitioning-wall pattern 360b may be arranged side by side and may be spaced apart from each other. The first partitioning-wall pattern 360a and the second partitioning-wall pattern 360b may extend along a column direction of the display part TU. The third partitioning-wall pattern 360c may be disposed between the first partitioning-wall pattern 360a and the second partitioning-wall pattern 360b. The third partitioning-wall pattern 360c may extend in a row direction intersecting the column direction in which the first and second partitioning-wall patterns 360a and 360b extend. Both opposing ends in the row direction of the third partitioning-wall pattern 360c may contact the first partitioning-wall pattern 360a and the second partitioning-wall pattern 360b, respectively.

The lower electrode 335 may be disposed on the switchable light-transmissive area TA of the display part TU. The lower electrode 335 may be positioned under the third partitioning-wall pattern 360c. For example, the lower electrode 335 may have a width larger than a width of a lower surface of the third partitioning-wall pattern 360c. Accordingly, the lower electrode 335 extends from the third partitioning-wall pattern 360c into the switchable light-transmissive area TA. A portion of the lower electrode 335 extending therefrom into the switchable light-transmissive area TA may be disposed to face the common line electrode 380 vertically (or up and down). The lower electrode 335 may include a transparent metal oxide such as indium-tin-oxide (ITO) or indium-zinc-oxide (IZO) to have the transmittance of the switchable light-transmissive area TA.

The lower electrode 335 may extend from the third partitioning-wall pattern 360c toward the pixel part PXA of the display part TU so as be electrically connected to one of the electrodes of the thin-film transistor TFT of FIG. 4. For example, the lower electrode 335 may be configured to extend from the first line electrode CE1 or the second line electrode CE2 which is electrically connected to a thin-film transistor TFT.

In a portion of the switchable light-transmissive area TA surrounded with the partitioning-wall pattern 360, the transmissive solution layer 365 including the plurality of electrophoretic particles 370 may be disposed. The transmissive solution layer 365 including the plurality of electrophoretic particles 370 may be sealed with the common line electrode 380, the second substrate 202, and the partitioning-wall pattern 360 disposed between the wiring substrate M-SUB and the display part TU. The switchable light-transmissive area TA may be switched to the light-transmissive area or the light-blocking area by controlling or adjusting the dispersion of the plurality of electrophoretic particles 370 based on the potential difference between the common line voltage applied to the common line electrode 380 disposed at the wiring substrate M-SUB and the high potential voltage (Vdd) transmitted by the link line LL disposed at the wiring substrate M-SUB.

Referring to FIG. 9, in a power-off (Voff) state in which power is not applied to the common line electrode 380, the plurality of electrophoretic particles 370 are widely dispersed within the transmissive solution layer 365. Accordingly, the switchable light-transmissive area TA may be a light-blocking state that does not transmit the light.

While the switchable light-transmissive area TA is in the light-blocking state, the common line voltage is applied to the common line electrode 380 in a power on (Von) state as shown in FIG. 10, such that the potential difference between the voltage of the lower electrode 335 and the voltage of the common line electrode 380 is generated. Thus, the electrophoretic particles 370 which have been widely dispersed within the transmissive solution layer 365 migrate to a disposition where the lower electrode 335 is disposed. For example, in an aspect of the present disclosure, the lower electrode 335 may be disposed under the third partitioning-wall pattern 360c of the partitioning-wall pattern 360. Thus, the electrophoretic particles 370 migrate toward the third partitioning-wall pattern 360c, as indicated by the arrow in FIG. 10. Thus, light transmits through the transmissive solution layer 365 filling the switchable light-transmissive area TA surrounded with the partitioning-wall pattern 360. Thus, the switchable light-transmissive area TA may be switched to a light-transmissive area in which an object or an image positioned in an opposite manner to the second substrate 202 is visible.

The switchable light-transmissive area TA may be converted to the transmissive area or the light-blocking area in each of the blocks BLK1, BLK2, BLK3, and BLK4, by transmitting different values of the common line voltage to different blocks BLK1, BLK2, BLK3, and BLK4 to generate different potential differences in different blocks BLK1, BLK2, BLK3, and BLK4, respectively. For example, the switchable light-transmissive area TA of the first block BLK1 may be converted to a light-transmissive area, and the switchable light-transmissive area TA of the second block BLK2 may be configured to be a light-blocking area. In this case, the display device may transmit the common line voltage to the common line electrode 380 in the first block BLK1 via the first voltage connection line 380a, while not transmitting the common line voltage to the second voltage connection line 380b. In this manner, the switchable light-transmissive area TA of each of the blocks BLK1, BLK2, BLK3, and BLK4 may be selectively converted to the transmissive area or the light-blocking area.

Accordingly, the area selected by the user may be switched to the light-transmissive area or the light-blocking area. Alternatively, the display device may operate selectively in the light-transmissive mode or the light-blocking mode, based on the use environment. This may improve user convenience. Furthermore, applicable fields of the display device according to an aspect of the present disclosure may be expanded compared to a display device whose an operation mode is limited to only the light-transmissive mode.

A display device according to various aspects of the present disclosure may be described as follows.

A display device according to various aspects of the present disclosure may comprise a wiring substrate including a first area and a second area, a plurality of link lines in the first area of the wiring substrate, a common line electrode in the second area of the wiring substrate, a plurality of display parts on the wiring substrate and spaced apart from each other, the plurality of display parts including a first area and a second area , the plurality of display parts including a plurality of light-emitting elements and a plurality of signal lines in the first area of the display part and a partitioning-wall pattern in the second area of the display part, and a transmissive solution layer disposed between the wiring substrate and each of the display parts and corresponding to the second area of the display parts, the transmissive solution layer including a plurality of electrophoretic particles. The second area of the display parts may include a lower electrode under the partitioning-wall pattern.

According to various aspects of the present disclosure, the wiring substrate may composed of a single substrate. The plurality of display parts may be arranged so as to be spaced apart from each other in row and column directions.

According to various aspects of the present disclosure, the first area may be a pixel area including a plurality of circuit patterns configured to drive the light-emitting element. The second area may be a switchable light-transmissive area configured to selectively switch to a light-blocking area or a light-transmissive area.

According to various aspects of the present disclosure, the common line electrode may be disposed at blocks of the second area of the wiring substrate.

According to various aspects of the present disclosure, the first area of the wiring substrate may include voltage connection lines. The voltage connection lines respectively may transfer different common line voltages to different common line electrodes respectively disposed at different blocks.

According to various aspects of the present disclosure, the display device may further comprise a plurality of first bonding members corresponding to the first area of the display part and are disposed between the display part and the wiring substrate. The plurality of first bonding member may be electrically connected to the plurality of link lines and the plurality of signal line.

According to various aspects of the present disclosure, the display device may further comprise a plurality of second bonding members corresponding to the first area of the display part. The plurality of first and second bonding members may be disposed in a same layer. The plurality of second bonding member may apply a high-potential voltage transmitted from the link line to the lower electrode.

According to various aspects of the present disclosure, the first bonding member may include a first spacer pattern providing a gap between the wiring substrate and the display part, a first conductive connection pattern covering an upper surface and an outer surface of the first spacer pattern, and a first adhesive pattern disposed on the first conductive connection pattern and in contact with the link line.

According to various aspects of the present disclosure, the second bonding member may include a second spacer pattern providing a gap between the wiring substrate and the display part, the first and second spacer patterns being disposed in ae same layer, a second conductive connection pattern covering an upper surface and an outer surface of the second spacer pattern and electrically connected to the lower electrode, and a second adhesive pattern disposed on the second conductive connection pattern and in contact with the link line.

According to various aspects of the present disclosure, the common line electrode or the lower electrode may include a transparent metal oxide including indium-tin-oxide or indium-zinc-oxide.

According to various aspects of the present disclosure, each of the plurality of display parts may include a plurality of thin-film transistors. The lower electrode may be electrically connected to the thin-film transistor.

According to various aspects of the present disclosure, the first area and the second area of the display parts may correspond to the first area and the second area of the wiring substrate, respectively.

A method for operating a display device according to various aspects of the present disclosure, the display device may comprise a wiring substrate including a first area having a plurality of link lines and a second area having a common line electrode and divided into a plurality of blocks, a plurality of display parts on the wiring substrate and spaced apart from each other, each of the plurality of display parts including a first area having a plurality of light-emitting elements and a plurality of signal lines and a second area having a partitioning-wall pattern, and a transmissive solution layer disposed between the wiring substrate and each of the display parts in the second area, the transmissive solution layer including a plurality of electrophoretic particles. The second area of the display parts may include a lower electrode under the partitioning-wall pattern. The method may comprise supplying a power to at least one of the common line electrode and the lower electrode of the blocks such that the plurality of electrophoretic particles migrate toward the partitioning-wall pattern so as to switch the second area of display parts into a light-transmissive area.

According to various aspects of the present disclosure, the first area may be a pixel area where a plurality of circuit patterns configured to drive the light-emitting element are disposed. The second area may be a switchable light-transmissive area configured to selectively switch to a light-blocking area or the light-transmissive area.

According to various aspects of the present disclosure, the common line electrode divided into the blocks may include at least a first block and a second block that are adjacent to each other. The switching the second area to the light-transmissive area may include applying a common line voltage to the first common line electrode except for the common line electrode of the second block, such that the second area of the first block is switched to the light-transmissive area, and the second area of the second block is configured to be a light-blocking area.

According to various aspects of the present disclosure, the method may further comprise stopping the power applying to the common line electrode and the lower electrode to switch the second area to a light-blocking mode.

According to various aspects of the present disclosure, the first area and the second area of the display parts may correspond to the first area and the second area of the wiring substrate, respectively.

A display device according to various aspects of the present disclosure may comprise a common line electrode; a lower electrode, a plurality of partitioning-wall pattern between the common line electrode and the lower electrode and connect the common line electrode and the lower electrode, and a transmissive solution layer disposed between the partitioning-wall pattern and including a plurality of electrophoretic particles. The display device may switch between a light-transmissive mode and a light-blocking mode by supplying voltage to at least one of the common line electrode and the lower electrode.

According to various aspects of the present disclosure, the common line electrode or the lower electrode may include a transparent metal oxide including indium-tin-oxide or indium-zinc-oxide.

According to various aspects of the present disclosure, the display device may further comprise a thin-film transistor connected to the lower electrode.

It will be apparent to those skilled in the art that various modifications and variations can be made in the display device and a method for operating the same of the present disclosure without departing from the technical idea or scope of the present disclosure. Thus, it is intended that the present disclosure cover the modifications and variations of this disclosure provided that within the scope of the claims and their equivalents.

The various aspects described above can be combined to provide further aspects. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the aspects can be modified, if necessary to employ concepts of the various patents, applications and publications to provide yet further aspects.

These and other changes can be made to the aspects in light of the above-detailed description. In general, in the following claims, the terms used should not be construed to limit the claims to the specific aspects disclosed in the specification and the claims, but should be construed to include all possible aspects along with the full scope of equivalents to which such claims are entitled. Accordingly, the claims are not limited by the disclosure.

1. A display device, comprising:
a wiring substrate including a first area and a second area;
a plurality of link lines in the first area of the wiring substrate;
a common line electrode in the second area of the wiring substrate;
a plurality of display parts on the wiring substrate and spaced apart from each other, each of the plurality of display parts having a first area and a second area, the plurality of display parts including:
a plurality of light-emitting elements and a plurality of signal lines in the first area of the display part; and
a partitioning-wall pattern in the second area of the display part; and
a transmissive solution layer disposed between the wiring substrate and each of the display parts and corresponding to the second area of the display parts, the transmissive solution layer including a plurality of electrophoretic particles,
wherein the second area of each of the display parts includes a lower electrode under the partitioning-wall pattern.

2. The display device of claim 1, wherein the wiring substrate is composed of a single substrate, and
wherein the plurality of display parts are arranged so as to be spaced apart from each other in row and column directions.

3. The display device of claim 1, wherein the first area is a pixel area including a plurality of circuit patterns configured to drive the light-emitting element, and
wherein the second area is a switchable light-transmissive area configured to selectively switch to a light-blocking area or a light-transmissive area.

4. The display device of claim 1, wherein the common line electrode is disposed at blocks of the second area of the wiring substrate.

5. The display device of claim 4, wherein the first area of the wiring substrate further includes voltage connection lines, and
wherein the voltage connection lines respectively transfer different common line voltages to different common line electrodes respectively disposed at different blocks.

6. The display device of claim 1, further comprising a plurality of first bonding members corresponding to the first area of the display parts and disposed between the display part and the wiring substrate,
wherein the plurality of first bonding member are electrically connected to the plurality of link lines and the plurality of signal line.

7. The display device of claim 6, further comprising a plurality of second bonding members corresponding to the first area of the display parts,
wherein the plurality of first and second bonding members are disposed in a same layer, and
wherein the plurality of second bonding member apply a high-potential voltage transmitted from the link line to the lower electrode.

8. The display device of claim 6, wherein the first bonding member includes:
a first spacer pattern providing a gap between the wiring substrate and the display part;
a first conductive connection pattern covering an upper surface and an outer surface of the first spacer pattern; and
a first adhesive pattern disposed on the first conductive connection pattern and in contact with the link line.

9. The display device of claim 8, wherein the second bonding member includes:
a second spacer pattern providing a gap between the wiring substrate and the display part, the first and second spacer patterns being disposed in a same layer;
a second conductive connection pattern covering an upper surface and an outer surface of the second spacer pattern and electrically connected to the lower electrode; and
a second adhesive pattern disposed on the second conductive connection pattern and in contact with the link line.

10. The display device of claim 1, wherein the common line electrode or the lower electrode includes a transparent metal oxide including either indium-tin-oxide or indium-zinc-oxide.

11. The display device of claim 1, wherein each of the plurality of display parts includes a plurality of thin-film transistors, and
wherein the lower electrode is electrically connected to the thin-film transistor.

12. The display device of claim 1, wherein the first area and the second area of the display parts correspond to the first area and the second area of the wiring substrate, respectively.

13. A method for operating a display device, wherein the display device includes:
a wiring substrate including a first area having a plurality of link lines and a second area having common line electrodes and divided into a plurality of blocks;
a plurality of display parts on the wiring substrate and spaced apart from each other, each of the plurality of display parts including a first area having a plurality of light-emitting elements and a plurality of signal lines and a second area having a partitioning-wall pattern; and
a transmissive solution layer disposed between the wiring substrate and each of the display parts and corresponding to the second area of the display parts, the transmissive solution layer including a plurality of electrophoretic particles,
wherein the second area of the display parts includes a lower electrode under the partitioning-wall pattern, and
wherein the method comprises:
supplying a power to at least one of the common line electrode and the lower electrode of the blocks such that the plurality of electrophoretic particles migrate toward the partitioning-wall pattern so as to switch the second area of the display parts into a light-transmissive area.

14. The method of claim 13, wherein the first area is a pixel area including a plurality of circuit patterns configured to drive the light-emitting element, and
wherein the second area is a switchable light-transmissive area configured to selectively switch to a light-blocking area or the light-transmissive area.

15. The method of claim 13, wherein the common line electrode divided into the blocks includes at least a first block and a second block that are adjacent to each other,
wherein switching the second area to the light-transmissive area includes:
applying a common line voltage to the first common line electrode except for the common line electrode of the second block, such that the second area of the first block is switched to the light-transmissive area, and the second area of the second block is configured to be a light-blocking area.

16. The method of claim 13, further comprising stopping the power applying to the common line electrode and the lower electrode to switch the second area to a light-blocking mode.

17. The method of claim 13, wherein the first area and the second area of the display parts correspond to the first area and the second area of the wiring substrate, respectively.

18. A display device, comprising:
a common line electrode;
a lower electrode;
a plurality of partitioning-wall pattern between the common line electrode and the lower electrode and connected the common line electrode and the lower electrode; and
a transmissive solution layer disposed between the partitioning-wall pattern and including a plurality of electrophoretic particles,
wherein the display device switches between a light-transmissive mode and a light-blocking mode by supplying voltage to at least one of the common line electrode and the lower electrode.

19. The display device of claim 18, wherein the common line electrode or the lower electrode includes a transparent metal oxide including indium-tin-oxide or indium-zinc-oxide.

20. The display device of claim 18, further comprising a thin-film transistor connected to the lower electrode.
